(19) United States
(12) Patent Application Publication
(10) Pub. No.: US 2019/0320796 A1
(43) Pub. Date: Oct. 24, 2019

(54) Economical and Eco-friendly Aluminum Profile Equipment Cabinet

(71) Applicant: SUZHOU A-RACK ENCLOSURE SYSTEMS CO., LTD, Suzhou, Jiangsu (CN)

(72) Inventor: ZhiYong DING, Suzhou (CN)

(73) Assignee: Suzhou A-Rack Enclosure Systems Co., Ltd., Suzhou, Jiangsu (CN)

(21) Appl. No.: 15/860,070

(22) PCT Filed: Jul. 31, 2017
(86) PCT No.: PCT/CN2017/095186

§ 371 Date: Jul. 10, 2019

(30) Foreign Application Priority Data
Jun. 12, 2017 (CN) 201710437873.2

(51) Int. Cl. A47B 96/14; G06F 1/18; H05K 5/02

(52) U.S. Cl. CPC A47B 96/1416; A47B 96/1466; H05K 5/0226; G06F 1/181

(57) ABSTRACT

An economical and eco-friendly aluminum profile cabinet comprises a first frame, a second frame, two side plates, a door plate and a top plate. The first and second frames are formed by splicing three aluminum profiles, with two adjacent aluminum profiles being fixed by a fastener. A first end of each side plate is clamped in a clamping groove of the aluminum profile of the first frame, and a second end parallel with the first end is clamped in a clamping groove of the aluminum profile of the second frame corresponding to the aluminum profile of first frame. A first end of one side wall of door plate hinges to the aluminum profile of first frame. A second end of one side wall of door plate is hinged to the aluminum profile of the second frame. The top plate is clamped in clamping grooves from the first frame aluminum profile.

### CROSS REFERENCE OF RELATED APPLICATIONS

This application claims the benefits of International application no. PCT/CN2017/095186, filed Jul. 31, 2017 and entitled ALUMINUM PROFILE EQUIPMENT CABINET, which provisional application is incorporated by reference herein in its entirety.

### FIELD OF THE INVENTION

The present invention relates generally to an economical and eco-friendly aluminum profile cabinet for maintaining a secure and stable environment for sensitive processor equipment; and especially in a data center. More so, the present invention relates to an aluminum profile equipment cabinet that is configured to mount processors, switches, knobs, and displays and to prevent electrical shock to equipment users and protect the contents from the environment; whereby the aluminum profile equipment cabinet is effective for protecting stored processor equipment, shielding the processor equipment against electromagnetic interference, storing processor equipment in an organized manner, being manufactured as nonstandard customized equipment cabinet, being manufactured from aluminum, so as to reduce surface treatment process, being quickly assembled directly from the manufacturer, and being economical and environment-friendly.

### BACKGROUND OF THE INVENTION

The following background information may present examples of specific aspects of the prior art (e.g., without limitation, approaches, facts, or common wisdom) that, while expected to be helpful to further educate the reader as to additional aspects of the prior art, is not to be construed as limiting the present invention, or any embodiments thereof, to anything stated or implied therein or inferred thereupon.

Typically, profile cabinets are used to securely store computers and sensitive control equipment. Such profile cabinets are often fabricated from cold-rolled steel or alloy. These containers provide protection for the stored equipment, shield electromagnetic interference, and arrange the equipment orderly and neatly, so as to facilitate follow-up maintenance of the equipment. The profile cabinets are generally classified into server containers, network containers, console containers, etc.

Generally, equipment cabinets, are fabricated from cold-rolled steel sheets or alloy through a standard welding process known in the art. The equipment cabinet generally serves to store computers, servers or related control equipment, can realize protection for the stored equipment, shield electromagnetic interference and arrange the equipment orderly and tidily, and are convenient for equipment maintenance.

Most equipment cabinets are generally divided into server equipment cabinets, network equipment cabinets, etc. The equipment cabinets systematically solve difficult problems of high-density heat radiation, attachment and management of plenty of cables, large-capacity power distribution and comprehensive compatibility with rack type equipment of different manufacturers.

This is known to cause a data center to be operated under a highly stable environment. The equipment cabinets have become indispensable articles in the computer industry. There are multiple types of equipment cabinets in a computer room. With continuous breakthrough of the computer industry, functions embodied by the equipment cabinets are becoming more diverse.

In related arts, the metal plate equipment cabinets are manufactured by the welding process. Once completely manufactured according to specific models and sizes, structures of the equipment cabinets are difficult to change. Therefore, when there is a requirement on nonstandard customization, new equipment cabinets are remanufactured according to different models, and complex working procedures of welding and surface treatment are carried out; thus the manufacturing time is long and the processing cost is high.

Furthermore, the metal plate equipment cabinets manufactured by the welding process cannot be manufactured in a use site due to a complex manufacturing process and can only be transported to the use site after being completely machined in a factory, and thus the transportation is inconvenient. Besides, the metal plate cabinets are easily damaged and deformed due to bumping in a transportation process

Other proposals have involved equipment cabinets for storing processors, networks, and hardware, so as to provide secure storage and minimize electromagnetic and electrical problems. The problem with these equipment cabinets is that they are not manufactured as nonstandard customized equipment cabinet; or from aluminum, so as to reduce surface treatment process. Also, they are not easy or fast to assemble. Even though the above cited equipment cabinets meet some of the needs of the market, an economical and eco-friendly aluminum profile cabinet for maintaining a secure and stable environment for sensitive processor equipment to mount processors, switches, knobs, and displays and to prevent electrical shock to equipment users and protect the contents from the environment; and also being fabricated as nonstandard customized equipment cabinet from aluminum, so as to reduce surface treatment process, and being economical and environment-friendly is still desired.

### SUMMARY

Illustrative embodiments of the disclosure are generally directed to an economical and eco-friendly aluminum profile cabinet for maintaining a secure and stable environment for sensitive processor equipment; and especially in a data center. The aluminum profile equipment cabinet is configured to mount processors, switches, knobs, and displays and to prevent electrical shock to equipment users and protect the processor equipment from the environment.

Further, the aluminum profile equipment cabinet is effective for protecting stored processor equipment; shielding the processor equipment against electromagnetic interference; storing processor equipment in an organized manner; being manufactured as nonstandard customized equipment cabinet; being manufactured from aluminum, so as to reduce surface treatment process; being quickly assembled directly from the manufacturer; and being economical and environment-friendly.

In some embodiments, the aluminum profile equipment cabinet comprises a first frame, a second frame, at least two side plates, at least one door plate and a top plate. The first frame and the second frame are vertically parallel and are disposed symmetrically, and are both formed by splicing at least three aluminum profiles, and two adjacent aluminum profiles are fixed by a fastener.

In one non-limiting embodiment, a first end of each side plate is clamped in a clamping groove of the aluminum profile of the first frame, and a second end parallel with the first end is clamped in a clamping groove of the aluminum profile of the second frame corresponding to the aluminum profile of the first frame.

A first end of one side wall of the door plate is hinged to the aluminum profile of the first frame and a second end of one side wall of the door plate is hinged to the aluminum profile of the second frame. The top plate is clamped in the clamping grooves of the aluminum profiles of the first frame.

Optionally, the first frame and the second frame are both rectangular frames spliced by four aluminum profiles.

Optionally, the four aluminum profiles of the first frame comprise two oppositely disposed first aluminum profiles and two oppositely disposed second aluminum profiles, and one side surface of each first aluminum profile is provided with a first clamping groove along a length direction thereof, which is configured for clamping the side plate.

The four aluminum profiles of the second frame comprise two oppositely disposed first aluminum profiles and two oppositely disposed second aluminum profiles, and one side surface of each first aluminum profile is provided with a first clamping groove along a length direction thereof, which is configured for clamping the side plate.

Optionally, at least two support pillars are disposed in a parallel manner between the second aluminum profiles of the first frame and the second aluminum profiles of the second frame, a first end of each support pillar is fixedly connected to the first frame and a second end of each support pillar is fixedly connected to the second frame.

Optionally, at least one third aluminum profile is disposed between the two oppositely disposed first aluminum profiles on the same side of the first frame and the second frame, and the third aluminum profile is fixed with the first aluminum profiles located on both ends of the third aluminum profile by the fasteners respectively.

Optionally, the fastener comprises a right-angled corner fitting, a first bolt, a second bolt, a first fastening block and a second fastening block; the first aluminum profile is provided with a fourth clamping groove along a length direction thereof, and the third aluminum profile is provided with a fifth clamping groove along a length direction thereof.

Further, the first bolt sequentially passes through a first side wall of the right-angled corner fitting, the fourth clamping groove and the first fastening block located in the fourth clamping groove, and the second bolt sequentially passes through a second side wall of the right-angled corner fitting, the fifth clamping groove and the second fastening block located in the fifth clamping groove, to realize fastening of the first aluminum profile and the third aluminum profile.

Optionally, a width of the fourth clamping groove is the same as a width of the fifth clamping groove.

Two parallel clamping bulges are disposed on outer surfaces of the first side wall and the second side wall, and the clamping bulges are perpendicular to the outer surfaces of the first side wall and the second side wall.

A distance between outer side walls of the two clamping bulges is the same as the width of the fourth clamping groove.

Optionally, the first clamping groove is a straight groove, and the fourth clamping groove and the fifth clamping groove are T-shaped grooves.

Optionally, the second aluminum profile is provided with a second clamping groove along a length direction thereof, a connector is fixedly connected in the second clamping groove, and the connector is hinged to the door plate.

Optionally, the second aluminum profile is further provided with a third clamping groove along the length direction thereof, and the two sides of the top plate are clamped in the third clamping grooves in the two second aluminum profiles on the first frame respectively.

According to the aluminum profile equipment cabinet provided by the present disclosure, the first frame and the second frame are formed by splicing at least three aluminum profiles. The two adjacent aluminum profiles are fixed by a fastener. The upper and lower ends of each side plate are clamped in the clamping grooves in the aluminum profiles of the first frame and the second frame respectively.

The upper and lower ends of one side wall of the door plate are hinged to the aluminum profiles on the first frame and the second frame respectively. The top plate is clamped in the clamping grooves of the aluminum profiles of the first frame. Connection of multiple parts can be realized without welding, such that the whole aluminum profile equipment cabinet can be spliced and assembled fast and compactly, and manufacturing of different nonstandard customized equipment cabinets is convenient.

In this manner, the aluminum profile equipment cabinet may be quickly assembled on-site, and damage and deformation of the whole equipment cabinet in a long-distance transportation process can be effectively avoided. Materials in the aluminum profile equipment cabinet in the present disclosure can be repeatedly used after disassembly for manufacturing new equipment cabinets, and economic and environment-friendly effects are realized. Besides, since the aluminum profile equipment cabinet in the present disclosure adopts the aluminum profiles, the equipment cabinet is lighter in whole weight and convenient to carry

One objective of the present invention is to securely receive and house various types, sizes, and powers of processor equipment, switches, knobs, and wires through easy arrangement of plates and racks.

Another objective is to provide an aluminum profile equipment cabinet that shields the processor equipment against electromagnetic interference.

Another objective is to prevent electrical shock to equipment users and protect the processor equipment from the environment.

Another objective is to enable expedited changing of the dimensions of the aluminum profile equipment cabinet.

Yet another objective is to provide an inexpensive to manufacture aluminum profile equipment cabinet, as used in data centers.

Yet another objective is to reduce the waste of production materials and surface treatment materials through use of welded aluminum.

Yet another objective is to make data centers more profitable by reducing the need to purchase new aluminum profile equipment cabinet when the processor eqipment needs change.

Other systems, devices, methods, features, and advantages will be or become apparent to one with skill in the art upon examination of the following drawings and detailed description. It is intended that all such additional systems, methods, features, and advantages be included within this description, be within the scope of the present disclosure, and be protected by the accompanying claims and drawings.

### BRIEF DESCRIPTION OF THE DRAWINGS

The invention will now be described, by way of example, with reference to the accompanying drawings, in which:

FIG. 1 is a structural schematic view of a frame of an aluminum profile equipment cabinet, in accordance with an embodiment of the present disclosure;

FIG. 2 is a partial enlarged view of part A in FIG. 1, in accordance with an embodiment of the present disclosure;

FIG. 3 is a partial enlarged view of part B in FIG. 1, in accordance with an embodiment of the present disclosure;

FIG. 4 is a mounting schematic view of a side plate of the aluminum profile equipment cabinet provided by the present embodiment, in accordance with an embodiment of the present disclosure;

FIG. 5 is a structural schematic view of the aluminum profile equipment cabinet provided by the present embodiment in a first direction, in accordance with an embodiment of the present disclosure;

FIG. 6 is a partial enlarged view of part C in FIG. 5, in accordance with an embodiment of the present disclosure;

FIG. 7 is a structural schematic view of the aluminum profile equipment cabinet provided by the present embodiment in a second direction, in accordance with an embodiment of the present disclosure;

FIG. 8 is a structural schematic view of a frame of a second aluminum profile equipment cabinet provided by the present embodiment, in accordance with an embodiment of the present disclosure; and

FIG. 9 is a structural schematic view of a frame of a third aluminum profile equipment cabinet provided by the present embodiment, in accordance with an embodiment of the present disclosure.

Like reference numerals refer to like parts throughout the various views of the drawings.

### DETAILED DESCRIPTION OF THE INVENTION

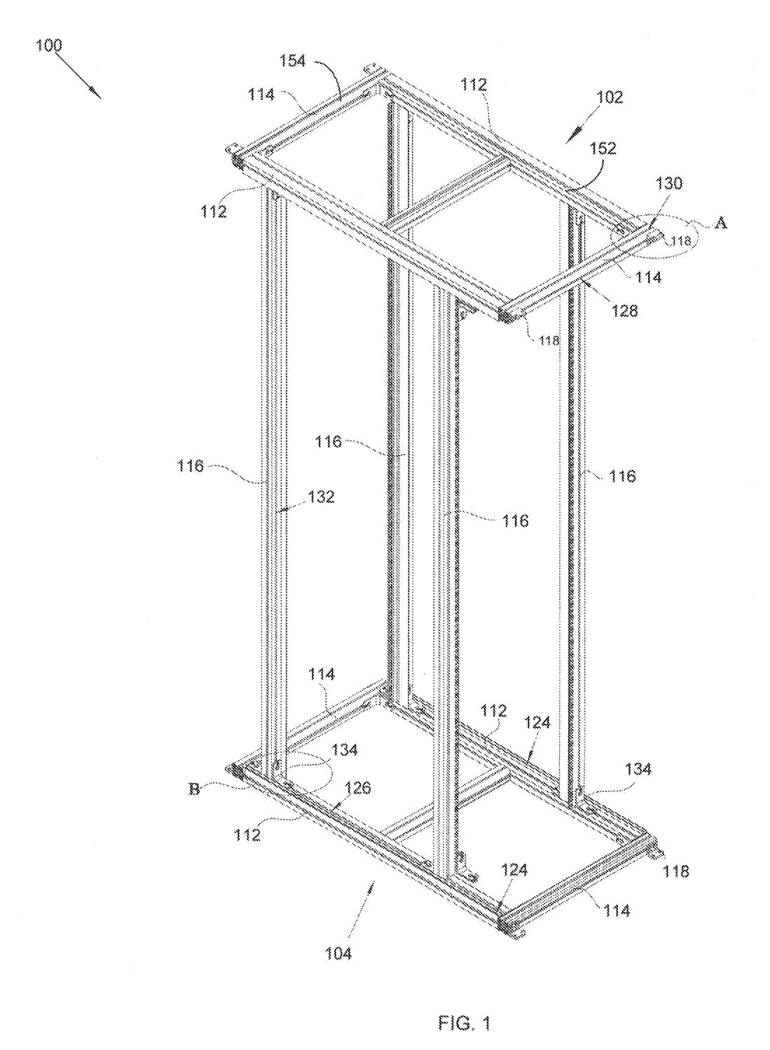

The following detailed description is merely exemplary in nature and is not intended to limit the described embodiments or the application and uses of the described embodiments. As used herein, the word “exemplary” or “illustrative” means “serving as an example, instance, or illustration.” Any implementation described herein as “exemplary” or “illustrative” is not necessarily to be construed as preferred or advantageous over other implementations. All of the implementations described below are exemplary implementations provided to enable persons skilled in the art to make or use the embodiments of the disclosure and are not intended to limit the scope of the disclosure, which is defined by the claims. For purposes of description herein, the terms “upper,” “lower,” “left,” “rear,” “right,” “front,” “vertical,” “horizontal,” and derivatives thereof shall relate to the invention as oriented in FIG. 1. Furthermore, there is no intention to be bound by any expressed or implied theory presented in the preceding technical field, background, brief summary or the following detailed description. It is also to be understood that the specific devices and processes illustrated in the attached drawings, and described in the following specification, are simply exemplary embodiments of the inventive concepts defined in the appended claims. Specific dimensions and other physical characteristics relating to the embodiments disclosed herein are therefore not to be considered as limiting, unless the claims expressly state otherwise.

An economical and eco-friendly aluminum profile cabinet 100 is referenced in FIGS. 1-9. As referenced in FIG. 1, the aluminum profile equipment cabinet 100 is configured to securely retain processor equipment, wires, switches, knobs, displays, and general sensitive processor equipment in a secure and stable environment, while protecting the equipment and users from electrical shock and electromagnetic interference. The manufacture of the aluminum profile equipment cabinet 100 is economical and environment-friendly, being fabricated from aluminum with minimal surface treatment.

In one embodiment, the aluminum profile equipment cabinet 100 is used in a data center. Though in other embodiment, the aluminum profile equipment cabinet 100 is operational in any environment that houses processor-related equipment. The aluminum profile equipment cabinet 100 utilizes a unique arrangement of frames, plates, and aluminum profiles to achieve an easy to assemble, reconfigurable, and eco-friendly storage site manufactured from welded aluminum and minimal surface treatment compositions.

Other unique equipment storage advantages provided by the aluminum profile equipment cabinet include: securely protecting stored processor equipment; shielding the processor equipment against electromagnetic interference; storing processor equipment in an organized manner; being manufactured as nonstandard customized equipment cabinet; being manufactured from aluminum, so as to reduce surface treatment process; being quickly assembled directly from the manufacturer; and being economical and environment-friendly.

As referenced in FIG. 1, some embodiments of the aluminum profile equipment cabinet 100 may include a first frame 102, a second frame 104, at least two side plates 106, at least one door plate 108 and a top plate 110, wherein the first frame 102 is an upper part frame of the aluminum profile equipment cabinet 100 and the second frame 104 is a lower part frame of the aluminum profile equipment cabinet 100.

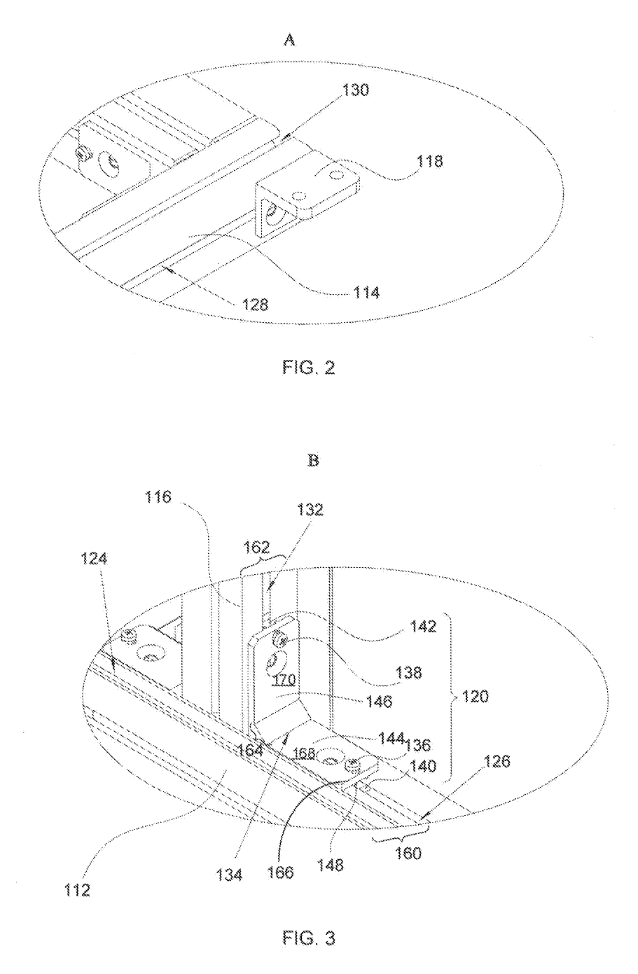

Turning now to FIG. 2, the first frame 102 and the second frame 104 are vertically parallel and disposed symmetrically and are both formed by splicing at least three aluminum profiles 112, 114, 116. Two adjacent aluminum profiles are fixed by a fastener 120. In the present embodiment, the first frame 102 and the second frame 104 which are both formed by splicing four aluminum profiles are taken as an example for explanation. Optionally, the first frame 102 and the second frame 104 are both rectangular frames spliced by four aluminum profiles.

As FIG. 3 illustrates, the upper end of each side plate 106 is clamped in clamping grooves 124, 126, 128, 130, 132 of the aluminum profiles of the first frame 102 while the lower end thereof is clamped in clamping grooves of the aluminum profiles of the second frame 104 corresponding to the aluminum profiles of the first frame 102.

The top end of one side wall 150 of the door plate 108 is hinged to the aluminum profiles of the first frame 102 while the bottom end thereof is hinged to the aluminum profiles of the second frame 104. The top plate 110 is clamped in the clamping grooves of the aluminum profiles of the first frame 102.

According to the aluminum profile equipment cabinet provided by the present embodiment, connection of multiple parts can be realized without welding, such that the whole aluminum profile equipment cabinet can be spliced and assembled fast and compactly, and manufacturing of different nonstandard customized equipment cabinets is convenient. The aluminum profile equipment cabinet in the present embodiment can be fast assembled in a use site, and damage and deformation of the whole equipment cabinet in a long-distance transportation process can be effectively avoided.

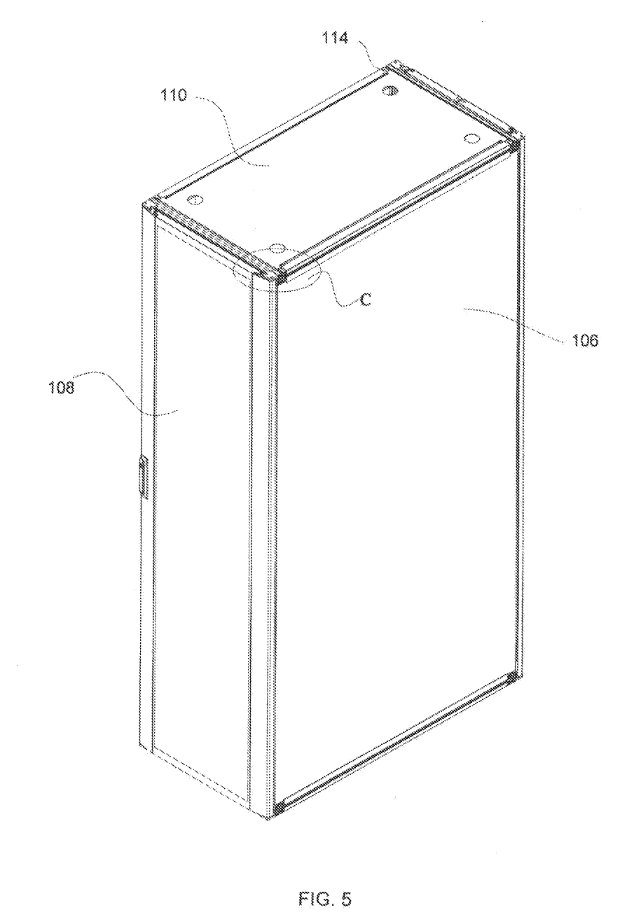

Materials in the aluminum profile equipment cabinet 100 can be repeatedly used after disassembly for manufacturing new equipment cabinets, and economic and environment-friendly effects are realized. Besides, since the aluminum profile equipment cabinet in the present embodiment adopts the aluminum profiles, the equipment cabinet is lighter in whole weight and convenient to carry (FIG. 5).

In addition, the aluminum profile equipment cabinet 100 needs no welding process and is economical and environment-friendly, and surface treatment processes can be reduced. The aluminum profiles are used as a raw material, such that a dead weight of the aluminum profile equipment cabinet can be effectively reduced, grounding conductivity is increased and mounting expandability is good.

As shown in FIG. 9, at least two support pillars 122 are disposed in a parallel manner between the second aluminum profiles 114 of the first frame 102 and the second aluminum profiles 114 of the second frame 104 on the aluminum profile equipment cabinet 100, and the upper end of each support pillar 122 is fixedly connected to the first frame 102 while the lower end thereof is fixedly connected to the second frame 104. The support pillars 122 can enhance the strength of the aluminum profile equipment cabinet 100, such that the aluminum profile equipment cabinet 100 can bear a larger load.

Optionally, the support pillars 122 are disposed in the corners of the first frame 102 and the second frame 104 between the first frame 102 and the second frame 104 of the aluminum profile equipment cabinet, and the upper ends of the support pillars 122 are fixedly connected to the first frame 102 while the lower ends thereof are fixedly connected to the second frame 104. In one embodiment, a first end 156 of each support pillar 122 is fixedly connected to the first frame 102 and a second end 158 of each support pillar is fixedly connected to the second frame 104.

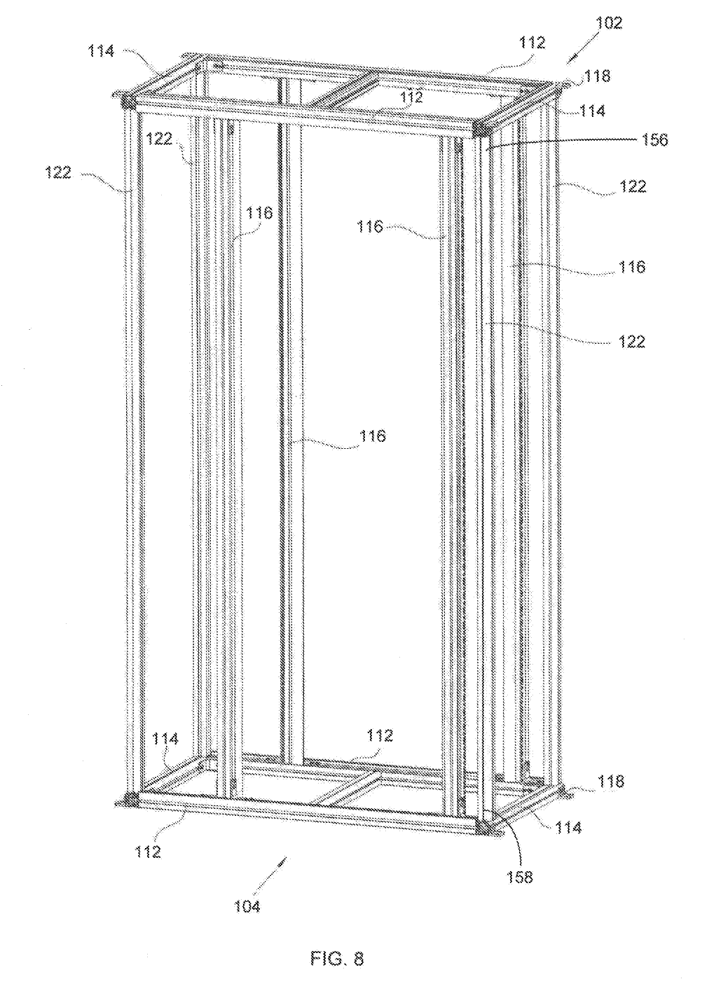

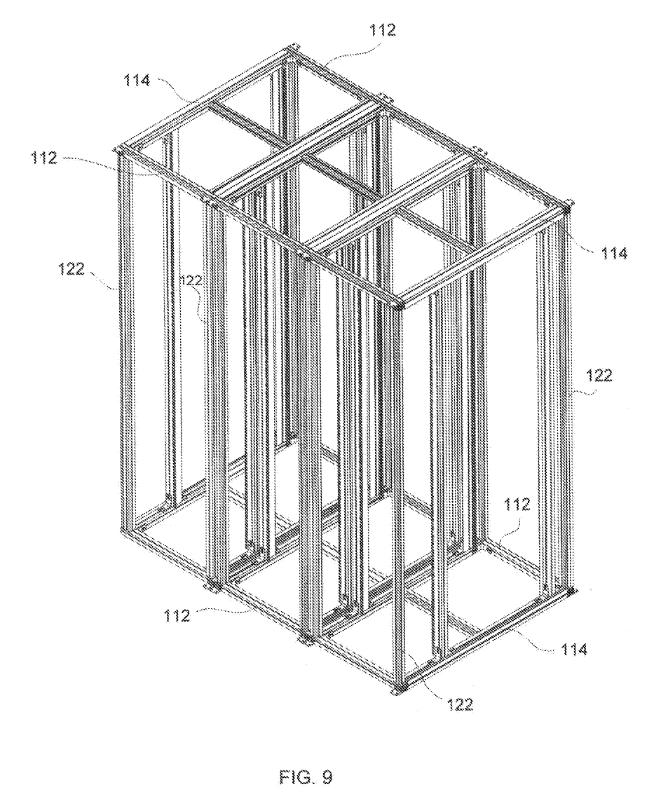

As shown in FIG. 8, one support pillar 122 is disposed in each of the four corners between the first frame 102 and the second frame 104 respectively, and there are four support pillars 122 in total, which are configured for enhancing the whole strength of the aluminum profile equipment cabinet, such that the aluminum profile equipment cabinet can bear the larger load. An amount of the support pillars 122 is determined according to an amount of the corners of the upper part frame 102 and the lower part frame 104, and the support pillars 122 are mounted after the side plates 106 are mounted.

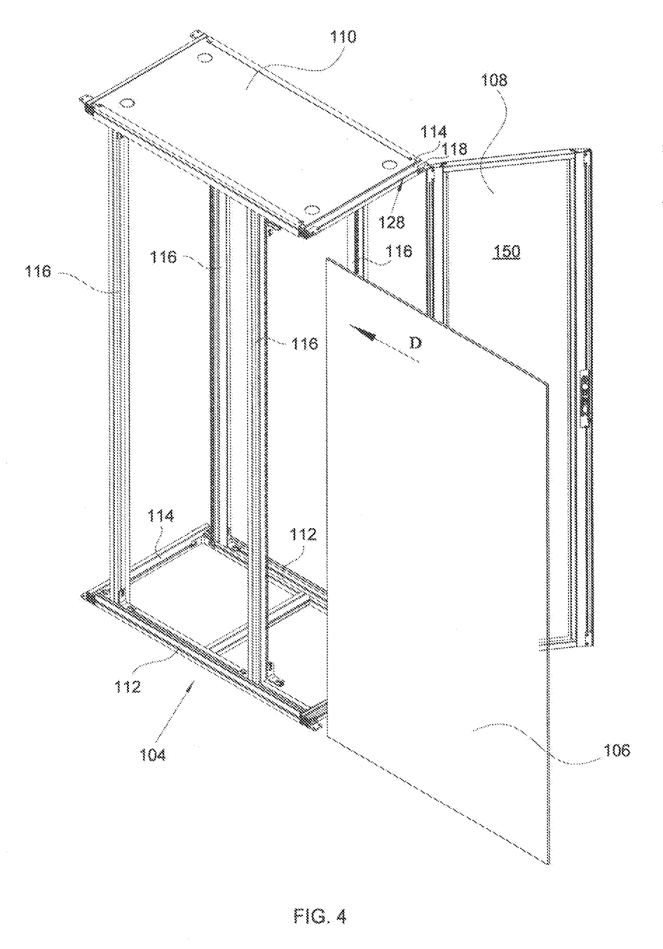

In addition, an amount of the door plate 108 may be determined according to the needs. The top plate 110 may be formed by a whole top plate, as shown in FIGS. 4 and 5, and may also be formed by multiple split top plates, as shown in FIGS. 8 and 9.

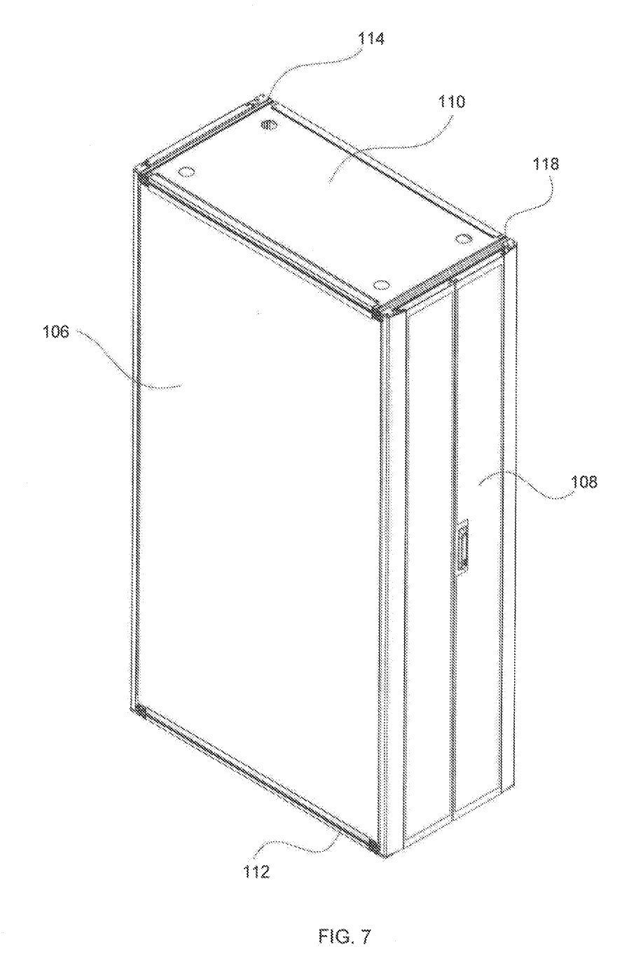

According to the aluminum profile equipment cabinet in FIG. 7, the first frame 102 and the second frame 104 are both rectangular frames spliced by four aluminum profiles. Optionally, the four aluminum profiles of the first frame 102 comprise two oppositely disposed first aluminum profiles 112 and two oppositely disposed second aluminum profiles 114, and the four aluminum profiles of the second frame 104 comprise two oppositely disposed first aluminum profiles 112 and two oppositely disposed second aluminum profiles 114, such that the first frame 102 and the second frame 104 are relatively steady in structure, and suitable for the shapes of common cabinets.

One side surface 152 of each first aluminum profile 112 is provided with a first clamping groove 124 along a length direction thereof, which is configured for clamping the side plate 106. Thus, the mounting of the side plates 106 can be realized by the first clamping grooves 124 in the first aluminum profiles 112. A mounting direction is the D direction as shown in FIG. 4, and no extra parts are required for connection. Mounting of the side plates 106 is fast and compact, a welding process is not needed, and economic and environment-friendly effects are realized.

At least one third aluminum profile 116 is disposed between the two oppositely disposed first aluminum profiles 112 on the same side of the first frame 102 and the second frame 104, and the third aluminum profile 116 is fixed with the first aluminum profiles 112 located on both ends of the third aluminum profile 116 by the fasteners 120 respectively. Due to the third aluminum profile 116, a supporting role is played for the whole aluminum profile equipment cabinet. In addition, the third aluminum profile 116 is provided with a support for placing a server.

Optionally, the fastener 120 comprises a right-angled corner fitting 134, a first bolt 136, a second bolt 138, a first fastening block 140 and a second fastening block 142 (FIG. 3). The first aluminum profile 112 is provided with a fourth clamping groove 126 along a length direction thereof. The third aluminum profile 116 is provided with a fifth clamping groove 132 along a longitudinal length direction.

The first bolt 136 sequentially passes through a first side wall 144 of the right-angled corner fitting 134, the fourth clamping groove 126 and the first fastening block 140 located in the fourth clamping groove 126, and the second bolt 138 sequentially passes through a second side wall 146 of the right-angled corner fitting 134, the fifth clamping groove 132 and the second fastening block 142 located in the fifth clamping groove 132, to realize fastening of the first aluminum profile 112 and the third aluminum profile 116.

Looking again at FIG. 3, a width 160 of the fourth clamping groove 126 is the same as a width 162 of the fifth clamping groove 132. Two parallel clamping bulges 148 are disposed on a first outer surface 168 of the first side wall 144 and a second outer surface 170 of the second side wall 146. The clamping bulges 148 are perpendicular to the outer surfaces 168, 170 of the first side wall 144 and the second side wall 146. A distance 164 between outer side walls 166 of the two clamping bulges 148 is the width 160 of the fourth clamping groove 126. The clamping bulges 148 can be clamped in the fourth clamping grooves 162 and the fifth clamping groove 132 tightly, such that the fastening between the fasteners 120 and the first aluminum profiles 112 and the third aluminum profile 116 is tight.

Turning to FIG. 4, one side surface 154 of the second aluminum profile 114 is provided with a second clamping groove 128 along a length direction thereof, a connector 118 is fixedly connected in the second clamping groove 128, and the connector 118 is hinged to the door plate 108. The mounting of the door plate 108 can be realized by the processed grooves in the second aluminum profiles 114 without a welding process, such that the door plate 108 is fast and compact to mount, and is economical and environment-friendly.

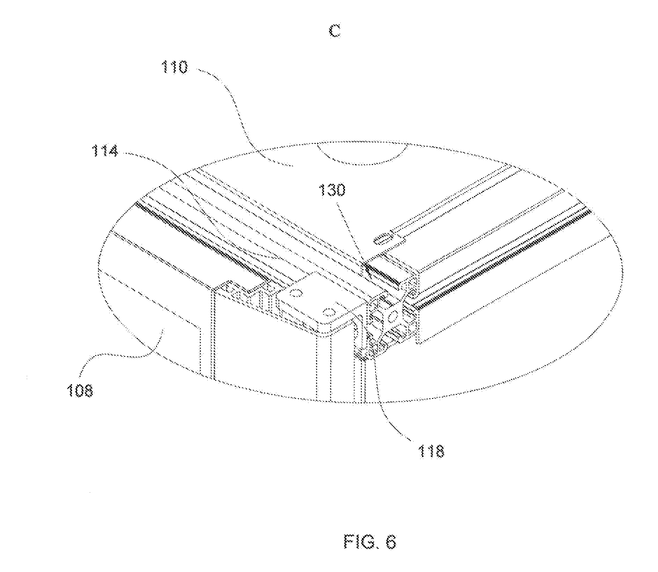

As FIG. 6 shows, the second aluminum profile 114 is further provided with a third clamping groove 130 along the length direction thereof, and both sides of the top plate 110 are clamped in the third clamping grooves 172 in the two second aluminum profiles 114 on the first frame 102 respectively. The mounting of the top plate 110 is realized by the processed grooves in the second aluminum profiles 114, so the mounting is fast and compact, and economic and environment-friendly effects are realized.

Optionally, the first clamping grooves 124 are straight grooves, and are convenient for drawing the side plate 106 in a mounting or demounting process. The fourth clamping grooves 162 and the fifth clamping grooves 132 are T-shaped grooves, and are convenient for locking and fixing other parts by the fasteners 120. The second clamping grooves 128 are T-shaped grooves, and are convenient for hinging and fixing the door plate 108 by the connectors 118. The third clamping grooves 172 are straight grooves, and are convenient for drawing the top plate 110 in a mounting or demounting process.

These and other advantages of the invention will be further understood and appreciated by those skilled in the art by reference to the following written specification, claims and appended drawings.

Because many modifications, variations, and changes in detail can be made to the described preferred embodiments of the invention, it is intended that all matters in the foregoing description and shown in the accompanying drawings be interpreted as illustrative and not in a limiting sense. Thus, the scope of the invention should be determined by the appended claims and their legal equivalence.

What is claimed is:

1-20. (canceled)

21. An economical and eco-friendly aluminum profile cabinet, comprising: a first frame, a second frame, at least two side plates, at least one door plate, and a top plate, wherein the first frame and the second frame are both formed by splicing at least three aluminum profiles, wherein the aluminum profiles of the first frame and the aluminum profiles of the second frame are disposed in a parallel and symmetrical manner, wherein two adjacent aluminum profiles of the first frame are fixed by a fastener, and two adjacent aluminum profiles of the second frame are fixed by a fastener; wherein
each of the side plate comprises a first end and a second end, wherein the first end of each side plate is clamped in a clamping groove of the aluminum profile of the first frame, and the second end parallel with the first end is clamped in a clamping groove of the aluminum profile of the second frame corresponding to the aluminum profile of the first frame; wherein
the door plate comprises one side wall having a first end and a second end, wherein the the first end of the side wall of the door plate is hinged to the aluminum profile of the first frame, and the second end of one side wall of the door plate is hinged to the aluminum profile of the second frame; and
the top plate is clamped in the clamping grooves of the aluminum profiles of the first frame.

22. The aluminum profile cabinet according to claim 21, wherein the first frame and the second frame are both rectangular frames spliced by four aluminum profiles.

23. The aluminum profile cabinet according to claim 22, wherein the four aluminum profiles of the first frame comprise two oppositely disposed first aluminum profiles and two oppositely disposed second aluminum profiles, wherein one side surface of each first aluminum profile is provided with a first clamping groove along a longitudinal direction thereof, which is configured for clamping the side plate; and
the four aluminum profiles of the second frame comprise two oppositely disposed first aluminum profiles and two oppositely disposed second aluminum profiles, and one side surface of each first aluminum profile is provided with a first clamping groove along a longitudinal direction thereof, which is configured for clamping the side plate.

24. The aluminum profile cabinet according to claim 23, wherein at least two support pillars are disposed in a parallel manner between the second aluminum profiles of the first frame and the second aluminum profiles of the second frame, wherein each of the pillars comprises a first end and a second end, wherein the first end of each support pillar is fixedly connected to the first frame and the second end of each support pillar is fixedly connected to the second frame.

25. The aluminum profile cabinet according to claim 24, wherein at least one third aluminum profile is disposed between the two oppositely disposed first aluminum profiles on the same side of the first frame and the second frame, and the third aluminum profile is fixed with the first aluminum profiles located on both ends of the third aluminum profile by the fasteners respectively.

26. The aluminum profile cabinet according to claim 25, wherein the fastener comprises a right-angled corner fitting, a first bolt, a second bolt, a first fastening block and a second fastening block; wherein the first aluminum profile is provided with a fourth clamping groove along a longitudinal direction thereof, and the third aluminum profile is provided with a fifth clamping groove along a longitudinal direction thereof; wherein the first bolt sequentially passes through a first side wall of the right-angled corner fitting, the fourth clamping groove, and the first fastening block located in the fourth clamping groove, and the second bolt sequentially passes through a second side wall of the right-angled corner fitting, the fifth clamping groove, and the second fastening block located in the fifth clamping groove to fasten the first aluminum profile with the third aluminum profile.

27. The aluminum profile cabinet according to claim 26, wherein a width of the fourth clamping groove is the same as a width of the fifth clamping groove;
two parallel clamping bulges are disposed on outer surfaces of the first side wall and the second side wall, and the clamping bulges are perpendicular to the outer surfaces of the first side wall and the second side wall; and
a distance between outer side walls of the two clamping bulges is the same as the width of the fourth clamping groove.

28. The aluminum profile cabinet according to claim 27, wherein the first clamping groove is a straight groove, and the fourth clamping groove and the fifth clamping groove are T-shaped grooves.

29. The aluminum profile cabinet according to claim 24, wherein the second aluminum profile is provided with a second clamping groove along a longitudinal direction thereof, and a connector is fixedly connected in the second clamping groove, and the connector is hinged to the door plate.

30. The aluminum profile cabinet according to claim 29, wherein the second aluminum profile is further provided with a third clamping groove along a longitudinal direction thereof, and the two sides of the top plate are clamped in the third clamping grooves in the two second aluminum profiles on the first frame respectively.
